(19) United States
(12) Patent Application Publication
(10) Pub. No.: US 2013/0309795 A1
(43) Pub. Date: Nov. 21, 2013

(54) METHOD FOR MANUFACTURING LED CHIP WITH INCLINED SIDE SURFACE

(71) Applicant: ADVANCED OPTOELECTRONIC TECHNOLOGY, INC., (US)

(72) Inventors: CHIA-HUI SHEN, Hsinchu (TW); TZU-CHIEN HUNG, Hsinchu (TW)

(73) Assignee: ADVANCED OPTOELECTRONIC TECHNOLOGY, INC., Hsinchu Hsien 303 (TW)

(21) Appl. No.: 13/875,294

(22) Filed: May 2, 2013

(30) Foreign Application Priority Data
May 17, 2012 (CN) 2012101533625

(51) Int. Cl. H01L 33/20

(52) U.S. Cl. CPC H01L 33/20
USPC 438/40

(57) ABSTRACT

A method for manufacturing an LED chip is disclosed wherein a substrate is provided. A first semi-conductor layer is formed on the substrate. A photoresist layer with an inverted truncated cone shape and a blocking layer with an inclined inner surface facing and surrounding the photoresist layer are formed on the first semi-conductor layer. The photoresist layer is removed and an epitaxial region surrounded by the blocking layer is defined. A lighting structure is formed inside the epitaxial region. The blocking layer is then removed and the first semi-conductor layer is exposed. Electrodes are formed and respectively electrically connected to the first semi-conductor layer and the lighting structure.

### BACKGROUND

1. Technical Field

The present disclosure relates to methods for manufacturing light emitting devices, and more particularly, to a method for manufacturing an LED (light emitting diode) chip with inclined side surfaces.

2. Description of Related Art

LEDs (Light-Emitting Diodes) have many advantages, such as high luminosity, low operational voltage, low power consumption, compatibility with integrated circuits, easy driving, long term reliability, and environmental friendliness. Such advantages have promoted the wide use of the LEDs as a light source. Generally, LED chips with inverted truncated cone shape have increased viewing angles and improved lighting output thereof. Typically, LED chips which have inverted truncated cone shape are manufactured by etching, such as wet etching of the LED chips. However, corroding angle of wet etching method is limited to lattice direction of the LED chips. Thus, the LED chip having an inverted truncated cone shape manufactured by wet etching has the lateral side thereof inclined only in an predetermined angle, which at times cannot meet the required application of the LED chip.

What is needed, therefore, is a method for manufacturing an LED chip with inclined side surface which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first step of a method for manufacturing an LED chip in accordance with a first embodiment of the present disclosure.

FIG. 2 shows a second step of the method for manufacturing the LED chip in accordance with the first embodiment of the present disclosure.

FIG. 3 shows a third step of the method for manufacturing the LED chip in accordance with the first embodiment of the present disclosure.

FIG. 4 shows a fourth step of the method for manufacturing the LED chip in accordance with the first embodiment of the present disclosure.

FIG. 5 shows a fifth step of the method for manufacturing the LED chip in accordance with the first embodiment of the present disclosure.

FIG. 6 shows a sixth step of the method for manufacturing the LED chip in accordance with the first embodiment of the present disclosure.

FIG. 7 shows a seventh step of the method for manufacturing the LED chip in accordance with the first embodiment of the present disclosure.

### DETAILED DESCRIPTION OF THE EMBODIMENTS

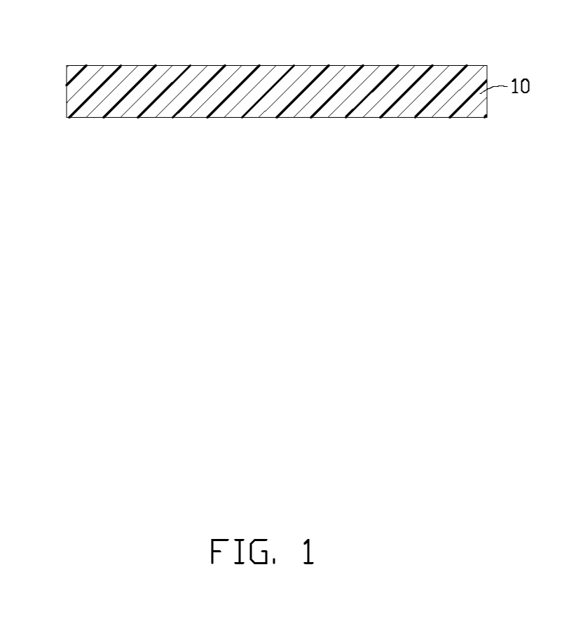

Referring to FIGS. 1-7, a method for manufacturing an LED chip 100 in accordance with a first embodiment of the present disclosure is shown. The method mainly includes several steps as discussed below.

Firstly, a substrate 10 is provided as shown in FIG. 1. The substrate 10 works as a supporting base for growing semi-conductor layers thereon, as discussed below. The substrate 10 is made of materials such as silicon, carbine silicon, sapphire, ceramics, etc. The substrate 10 can also be chosen to use a flexible material with viscosity and be removed after growing the semi-conductor layers thereon, as discussed below.

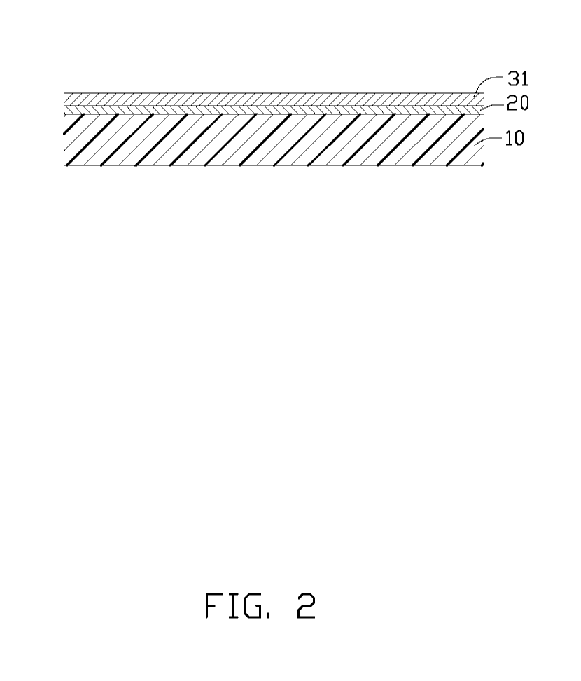

As shown in FIG. 2, a buffer layer 20 and a first semi-conductor layer 31 are grown in sequence on a top surface of the substrate 10. In this embodiment, the first semi-conductor layer 31 is an N-type GaN layer. The buffer layer 20 is an undoped GaN layer. Both the buffer layer 20 and the first semi-conductor layer 31 are formed by MOCVD (Metal-Organic Chemical Vapor Deposition). The buffer layer 20 completely covers the substrate 10, and the first semi-conductor layer 31 completely covers the buffer layer 20. The buffer layer 20 is used to reduce lattice mismatch between the first semi-conductor layer 31 and the substrate 10, so that the first semi-conductor layer 31 will grow with better quality. It is understood that, the buffer layer 20 can also be simultaneously removed when the substrate 10 is removed.

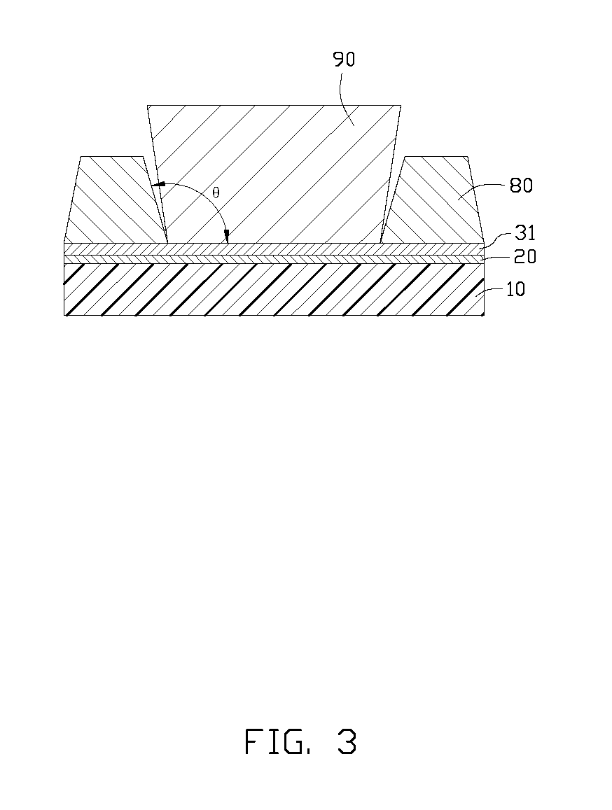

As shown in FIG. 3, a photoresist layer 90 which has a trapezoidal cross-section with an inclined periphery surface shown in FIG. 3 is formed on the first semi-conductor layer 31. The photoresist layer 90 is formed as an inverted truncated cone shape by photolithography process. An angle between the periphery surface of the photoresist layer 90 and the first semi-conductor layer 31 is less than 90 degrees. A center of the photoresist layer 90 is coincident with or adjacent to a center of the first semi-conductor layer 31. Then a blocking layer 80 is formed around the photoresist layer 90. The blocking layer 80 defines a cavity which has a trapezoidal cross-section for receiving the photoresist layer 90 therein. It is preferred that, a height of the blocking layer 80 is less than a height of the photoresist layer 90. The blocking layer 80 is made of silicon dioxide and formed by CVD (Chemical Vapor Deposition). An inner surface of the blocking layer 80 defining the cavity is inclined relative to the first semi-conductor layer 31 by an obtuse angle. An angle θ between the inner side surface of the blocking layer 80 and the first semi-conductor layer 31 is greater than 90 degrees, preferably larger than 120 degrees. The angle θ is determined by relevant parameters of the photolithography process and conditions of the CVD process. It is understood that because the shape of the photoresist layer 90 is determined by photolithography process, the angle between the periphery surface of the photoresist layer 90 and the first semi-conductor layer 31 is adjustable in a large range. Thus, the angle θ can be changed within a range of angle by changing relevant parameters of the photolithography process and conditions of the CVD process.

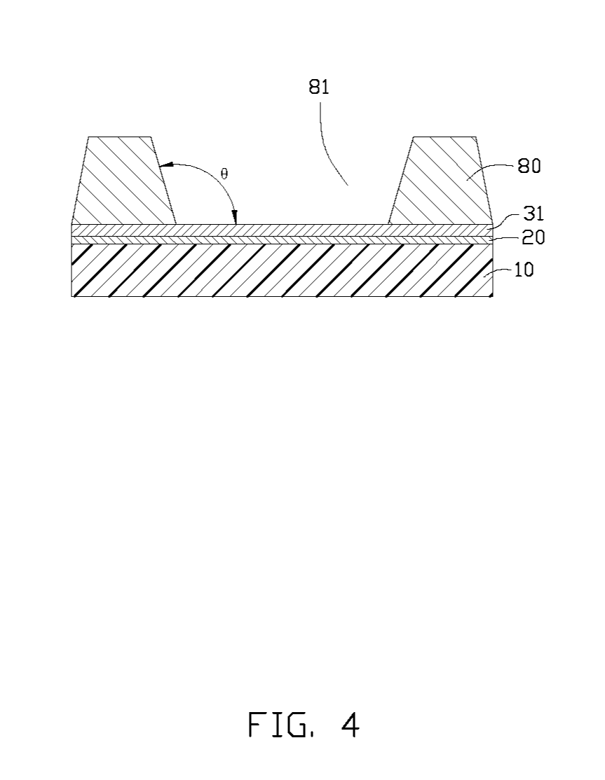

As shown in FIG. 4, the photoresist layer 90 is removed. An epitaxial region 81 is defined surrounded by the blocking layer 80. The epitaxial region 81 is also the cavity defined in the blocking layer 80. The first semi-conductor layer 31 is exposed in the epitaxial region 81.

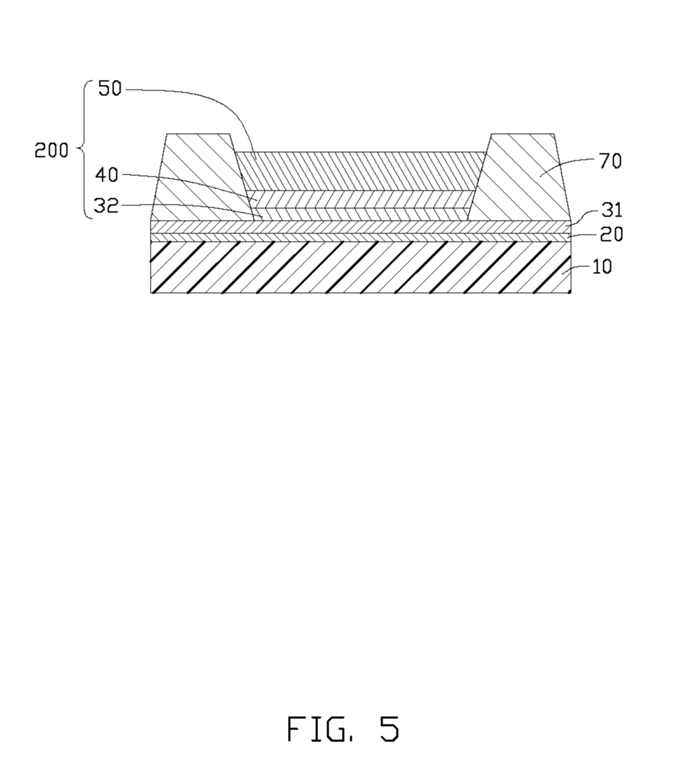

As shown in FIG. 5, a lighting structure 200 is formed inside the epitaxial region 81. The lighting structure 200 includes, in sequence from bottom to top, another first semi-conductor layer 32, an active layer 40 and a second semi-conductor layer 50. In this embodiment, the second semi-conductor layer 50 is a P-type GaN layer. The active layer 40 has a multi quantum well (MQW) structure. Each layer of the lighting structure 200 is formed by MOCVD. Each layers of the lighting structure 200 is made of GaN. The another first semi-conductor layer 32 is made of a material the same as that for forming the first semi-conductor layer 31. The lighting structure 200 grows along a height direction of the epitaxial region 81. The lighting structure 200 fully fills the epitaxial region 81. A contour of a lateral side the lighting structure 200 is corresponding to the inner side surface of the blocking layer 80.

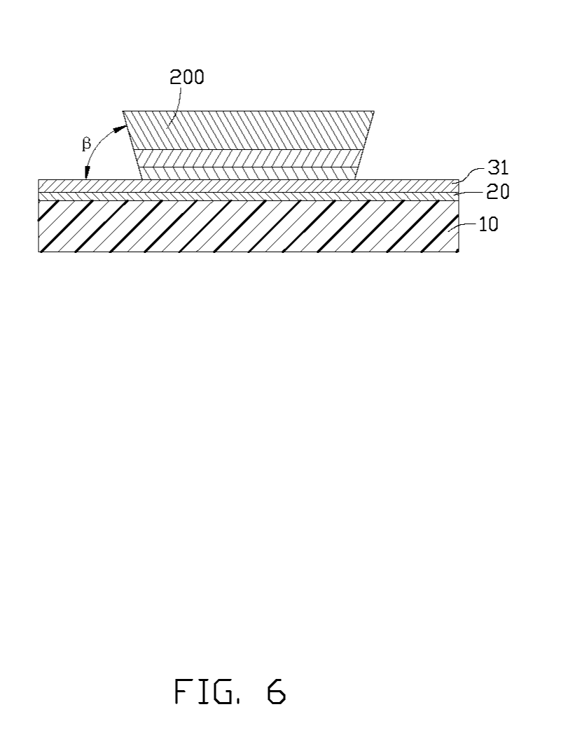

As shown in FIG. 6, the blocking layer 80 is removed, and accordingly a periphery surface of the lighting structure 200 including the another first semi-conductor layer 32, the active layer 40 and the second semi-conductor layer 50 is exposed. The blocking layer 80 can be removed by BOE (Buffer Oxide Etching). Portion of the first semi-conductor layer 31 once covered by the blocking layer 80 is exposed. An angle β which is a supplementary angle of the angle θ is defined between the periphery surface of the lighting structure 200 and the first semi-conductor layer 31. Degree of the angle β is less than 90 degrees and the lighting structure 200 appears as an inverted truncated cone shape.

Due to the degree of the angle θ between the blocking layer 50 and the first semi-conductor layer 31 can be within a range of angle, the angle β between the lighting structure 200 and the first semi-conductor layer 31 can also be within a range of angle. Thus, the side surface of the lighting structure 200 can be inclined in different angles.

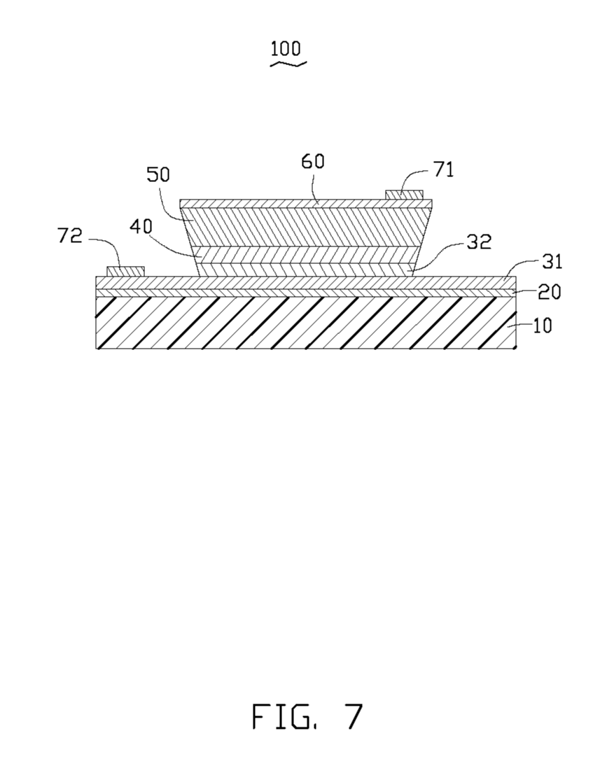

As shown in FIG. 7, a conducting layer 60 is formed on the second semi-conductor layer 50. The conducting layer 60 is made of transparent conductive materials such as ITO (Indium Tin Oxide). A first electrode 71 is formed on the conducting layer 60 and electrically connected to the second semi-conductor layer 50 via the conducting layer 60. A second electrode 72 is formed on and electrically connected to the first semi-conductor layer 31 and the another first semi-conductor layer 32 via the first semi-conductor layer 31. After that, the manufacture of the LED chip 100 is completed. The LED chip 100 emits light when the first electrode 71 and the second electrode 72 are connected to a power supply.

The LED chip 100 manufactured by the above steps includes a lighting structure 200 with an inclined periphery surface. Thus, the LED chip 100 achieves large viewing angle and improved lighting output. Since when the inclined periphery surface of the lighting structure 200 is exposed by etching the blocking layer 80, the first semi-conductor 31 is also exposed, a step for etching the lighting structure 200 to expose the first semi-conductor layer 31 to form a mesa by using ICP (Inductively Coupled Plasma) in the conventional LED manufacturing process can be omitted in the present disclosure. It is understood that, the substrate 10 and the buffer layer 20 can be removed after forming the lighting structure 200 or even after forming the electrodes 71, 72. The substrate 10 and the buffer layer 20 can be removed by ways of etching, polishing, etc.

It is understood that, the another first semi-conductor layer 32 can be omitted and the active layer 40 can be directly formed on the first semi-conductor layer 31. The first semi-conductor layer 31 and the another first semi-conductor layer 32 can be a P-type semiconductor layer, accordingly, the second semi-conductor layer 50 can be an N-type semiconductor layer.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing an LED (light emitting diode) chip, comprising:
providing a substrate;
forming a first semi-conductor layer on the substrate;
forming a photoresist layer with an inverted truncated cone shape and a blocking layer with an inclined inner surface facing and surrounding the photoresist layer on the first semi-conductor layer;
removing the photoresist layer and defining an epitaxial region surrounded by the inner surface of the blocking layer;
forming a lighting structure inside the epitaxial region;
removing the blocking layer and exposing the first semi-conductor layer; and
forming electrodes respectively electrically connecting the first semi-conductor layer and the lighting structure.

2. The method of claim 1, wherein the photoresist layer is formed by a photolithography process.

3. The method of claim 1, a center of the photoresist layer is coincident with or adjacent to a center of the first semi-conductor layer.

4. The method of claim 1, wherein a height of the blocking layer is less than a height of the photoresist layer.

5. The method of claim 1, wherein a periphery surface of the photoresist layer is inclined relative to the first semi-conductor layer by an acute angle, and the inner surface of the blocking layer is inclined relative to the first semi-conductor layer by an obtuse angle.

6. The method of claim 5, wherein an angle between the inner surface of the blocking layer and the first semi-conductor layer is greater than 120 degrees.

7. The method of claim 1, wherein the blocking layer is made of silicon dioxide and removed by buffer oxide etching.

8. The method of claim 1, wherein the lighting structure comprises an active layer and a second semi-conductor layer.

9. The method of claim 8, wherein the lighting structure further comprises another first semi-conductor layer between the first semi-conductor layer and the active layer.

10. The method of claim 9, wherein the another first semi-conductor layer is made of a material the same as that for forming the first semi-conductor layer.

11. The method of claim 10, wherein the first semi-conductor layer is an N-type layer, the second semi-conductor layer is a P-type layer.

12. The method of claim 1, wherein before the step of forming the first semi-conductor layer, a buffer layer is formed on the substrate.

13. The method of claim 12, wherein the substrate and the buffer layer are simultaneously removed after forming the lighting structure.

14. The method of claim 13, wherein an angle between a periphery surface of the lighting structure and the first semi-conductor layer is less than 90 degrees.

15. A method for manufacturing an LED (light emitting diode) chip, comprising:
providing a substrate;
forming a first semi-conductor layer on the substrate;
forming a photoresist layer and a blocking layer on the first semi-conductor layer, the photoresist layer having a trapezoidal cross-section, the blocking layer defining a cavity for receiving the photoresist layer therein;
removing the photoresist layer and defining an epitaxial region surrounded by the blocking layer;
forming a lighting structure inside the epitaxial region, the lighting structure having an active layer and a second semi-conductor layer formed on the first semi-conductor layer in sequence;
removing the blocking layer and exposing the first semi-conductor layer; and
forming electrodes respectively electrically connecting the first semi-conductor layer and the second semi-conductor layer.

16. The method of claim 15, wherein a periphery surface of the photoresist layer is inclined relative to the first semi-conductor layer by an acute angle, and an inner surface of the blocking layer is inclined relative to the first semi-conductor layer by an obtuse angle.

17. The method of claim 16, wherein an angle between the inner surface of the blocking layer and the first semi-conductor layer is greater than 120 degrees.

18. The method of claim 15, wherein a height of the blocking layer is less than a height of the photoresist layer.

19. The method of claim 15, wherein the photoresist layer is formed by a photolithography process.
